(19) United States
(12) Patent Application Publication
(10) Pub. No.: US 2016/0240500 A1
(43) Pub. Date: Aug. 18, 2016

(54) PACKAGED SEMICONDUCTOR DEVICES

(71) Applicants: CHIPMOS TECHNOLOGIES INC, HSINCHU (TW); CHIPMOS TECHNOLOGIES (BERMUDA) LTD., HAMILTON (BM)

(72) Inventor: CHUN FU HUANG, HSINCHU (TW)

(21) Appl. No.: 14/845,826

(22) Filed: Sep. 4, 2015

(30) Foreign Application Priority Data
Feb. 17, 2015 (TW) 104105505

(51) Int. Cl. H01L 23/00; H01L 23/31

(52) U.S. Cl. CPC H01L 24/13; H01L 23/3171; H01L 24/08; H01L 24/03; H01L 24/11; H01L 2224/05144; H01L 2224/05139; H01L 2224/05166; H01L 2224/05147; H01L 2224/02373; H01L 2224/0401; H01L 2224/13144; H01L 2224/13147; H01L 2224/13155; H01L 2224/13139; H01L 2224/05184; H01L 2224/13016; H01L 2924/0132; H01L 2924/0133; H01L 2924/2064; H01L 2224/03622

(57) ABSTRACT

A packaged semiconductor device is provided, which includes a substrate comprising a contact pad; a passivation layer disposed on the substrate, where the passivation layer covers part of the contact pad; an under bump metallization (UBM) layer disposed on the substrate, where the UBM layer is coupled to the contact pad; a conductive bump disposed on the UBM layer, where the conductive bump comprises a column connecting the UBM layer and a cap disposed on top of the column; and a solder ball encapsulating the conductive bump. The cap includes a bottom area larger than a cross-sectional area of the column, and a bottom of the cap is distant from an upper surface of the passivation layer by a space.

### BACKGROUND

With ever-changing semiconductor technology, the electronics industry has experienced a rapid revolution from thick film to thin film and the continuation of enhancements in miniaturization. Semiconductor packaging is a science of assembling electronic circuits by connecting semiconductor devices. It has developed at a fast pace along with the advances in the semiconductor and electronics industry.

In the manufacturing process of semiconductor packaging, bonding reliability between the solder ball and chips or other devices is required in order to avoid electrical failure or malfunction after packaging. In most situations, solder balls are attached to contact pads or conductive pillars. However, in practical cases, adherence failures of solder balls usually occur. Thus, the production of semiconductor packaging has not been effectively improved.

Therefore, it is crucial to improve bonding reliability by increasing the adhesion between solder balls and semiconductor devices.

### SUMMARY

An embodiment of the present disclosure provides a packaged semiconductor device, which includes a substrate comprising a contact pad; a passivation layer disposed on the substrate, where the passivation layer covers part of the contact pad; an under bump metallization (UBM) layer disposed on the substrate, where the UBM layer is coupled to the contact pad; a conductive bump disposed on the UBM layer, where the conductive bump comprises a column connecting the UBM layer and a cap disposed on top of the column, the cap including a bottom area larger than a cross-sectional area of the column and a bottom of the cap being distant from an upper surface of the passivation layer by a space; and a solder ball encapsulating the conductive bump.

In an embodiment, the bottom of the cap has a width larger than a width of the UBM layer.

In an embodiment, the solder ball encapsulates a sidewall of the column and the space.

In an embodiment, a top surface of the cap has a curvature with a central part of the cap that is thicker than a periphery of the cap.

In an embodiment, a top surface of the cap has a curvature with a central part of the cap that is thinner than a periphery of the cap.

In an embodiment, the conductive bump is made of gold, copper, nickel, silver or alloys thererof.

In an embodiment, the UBM layer is made of titanium-copper, titanium-tungsten-gold, or silver-containing alloy.

Another embodiment of the present disclosure provides a packaged semiconductor device. The packaged semiconductor device includes a substrate comprising a contact pad; a passivation layer disposed on the substrate, the passivation layer with a first part of the contact pad exposed; a redistribution layer disposed on the passivation layer and coupled to the first part of the contact pad; a protection layer disposed on the redistribution layer with a second part of the passivation layer exposed; a UBM layer disposed on the protection layer, the UBM layer being coupled to the second part of the passivation layer; a conductive bump disposed on the UBM layer, where the conductive bump comprises a column connecting the UBM layer and a cap disposed on top of the column, the cap including a bottom area larger than a cross-sectional area of the column and a bottom of the cap being distant from an upper surface of the passivation layer by a space; and a solder ball encapsulating the conductive bump.

Yet another embodiment of the present disclosure provides a method for manufacturing a packaged semiconductor device. The method comprises forming a substrate comprising a contact pad; forming a passivation layer on the substrate while exposing a first part of the contact pad; forming a UBM layer on the substrate to couple the UBM layer with the contact pad; forming a conductive bump on the UBM layer; and forming a solder ball encapsulating the conductive bump. The step of forming the conductive bump further comprises forming a column connecting the UBM layer and forming a cap on top of the column, in which the cap includes a bottom area larger than a cross-sectional area of the column, and a bottom of the cap is distant from an upper surface of the passivation layer by a space.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B are cross-sectional views of a packaged semiconductor device in accordance with some embodiments.

FIG. 2 is a cross-sectional view of a packaged semiconductor device according in accordance with some embodiments.

FIGS. 3A-3B are cross-sectional views of a method for manufacturing a packaged semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As the device dimensions shrink, it is important to improve adherence reliability by increasing adhesion between solder balls and semiconductor devices. The solder ball is disposed, for example, on an under bump metallization (UBM) layer, a redistribution layer (RDL) or a conductive pillar. In the existing approaches, a UBM layer may be formed at the bottom of the solder ball such that the solder ball is disposed on the UBM layer. In conventional approaches, the sidewall at the bottom of the solder ball aligns with the sidewall of the UBM layer. Alternatively, it is arranged that the bottom area of the solder ball in contact with the UBM layer is less than the area of the UBM layer. Consequently, the edge of the sidewall of the UBM layer or part of the UBM layer is exposed outside the circumference of the solder ball. The solder ball may drop since it is attached to the UBM layer merely by metal bonding.

In the present disclosure the edge of the UBM layer extends within the interior of the solder ball. The solder ball fully encapsulates the UBM layer, thereby strengthening the structure of the solder ball and keeping the solder ball from dropping. The bonding stability is thus enhanced.

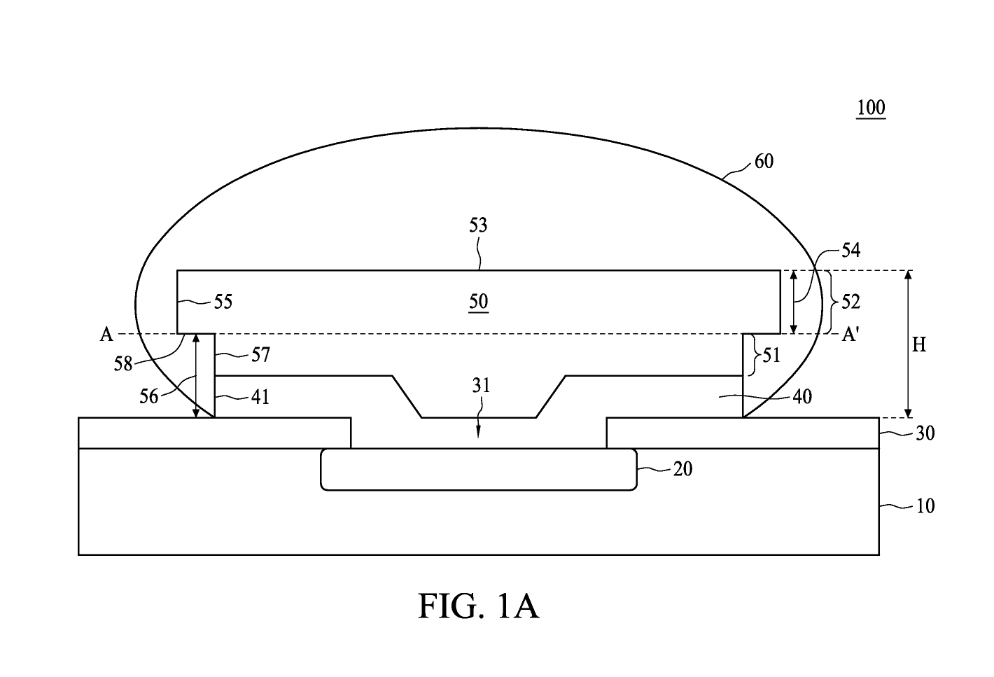

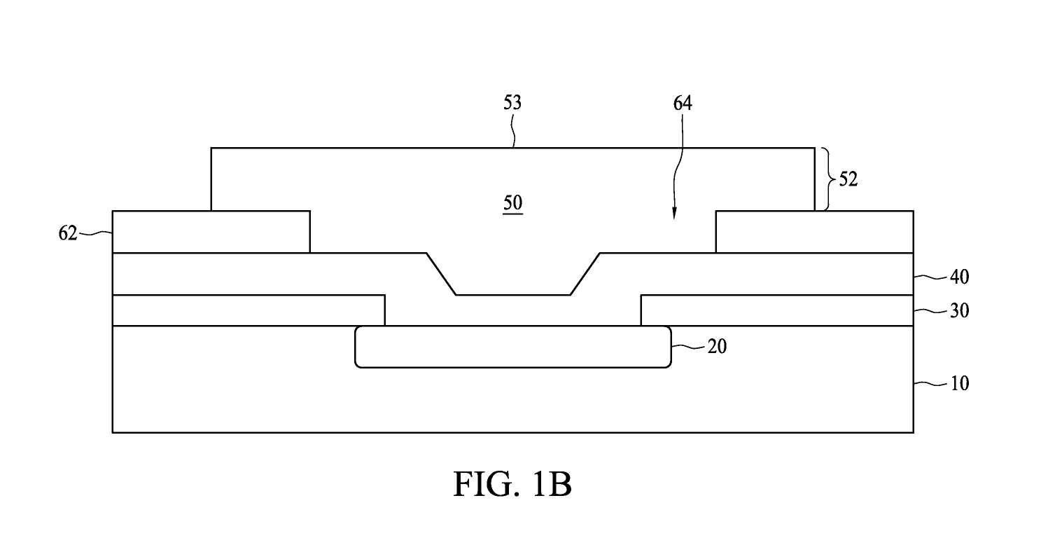

FIGS. 1A is a cross-sectional view of a packaged semiconductor device 100 in accordance with some embodiments. The semiconductor structure 100 comprises a substrate 10, a contact pad 20, a passivation layer 30, a UBM layer 40, a conductive bump 50 and a solder ball 60.

The substrate 10 has a semiconductor material, such as a silicon wafer, glass, ceramic, or the like. The substrate 10 includes an active surface and a passive surface opposite thereto. The contact pad 20 is disposed on the active surface of the substrate 10. The material of the contact pad 20 is selected preferably from gold, silver, copper, aluminum or alloys thereof. The contact pad 20 is used as a conductive contact to electrically connect the substrate 10 with external environments. The passivation layer 30 is disposed on the active surface of the substrate 10, and an opening 31, at a location corresponding to the contact pad 20, is defined to expose part of the contact pad 20.

The UBM layer 40 is disposed on the contact pad 20, which is exposed in an opening 31, and the UBM layer 40 is electrically connected with the contact pad 20. The UBM layer 40 comprises at least two metal layers (not shown), i.e., an adhesive layer such as a titanium, copper or nickel layer, and a seed layer, disposed on the adhesive layer, made of gold, copper, nickel, silver or an alloy thereof. Other suitable materials and layered configurations for the UBM layer 40 include titanium/copper, titanium/tungsten/gold, silver-containing alloy, chrome/chromium-copper alloy/copper/gold, titanium/titanium-tungsten/copper or copper/nickel/gold configurations. The UBM layer 40 is formed using a metal sputtering, physical vapor deposition or chemical vapor deposition process. Subsequently, the conductive bump 50 is formed on the UBM layer 40. The conductive bump 50 includes a column 51 and a cap 52. The column 51 connects downwardly with the UBM layer 40 and supports the cap 52 above the column 51. Furthermore, the width of the column 51 is equal to the width of the UBM layer 40 (distance between sidewalls 41), such that a sidewall 57 aligns with a sidewall 41 of the UBM layer 40. In addition, the bottom area of the cap 52 (with reference to a section line AN) is larger than the cross-sectional area of the column 51. In an embodiment, the cross-sectional area of the column 51 is about 5%-25% of the bottom area of the cap 52. In addition, the cap 52 has a thickness 54, which is measured from a highest point of a top surface 53 of the cap 52 to a bottom 58. The thickness 54 is about 10%-40% of a height H (distance from the top surface 53 of the cap 52 to an upper surface of the passivation layer 30). In a lateral view, the width of the bottom 58 of the cap 52 (distance between sidewalls 55) is larger than the width of the UBM layer 40 (distance between the sidewalls 41). That is to say, the periphery of the cap 52 protrudes from the column 51 so that a space 56 is generated between the bottom 58 of the cap 52 and the upper surface of the passivation layer 30.

Finally, the solder ball 60 is disposed on the conductive bump 50. The solder ball 60 is made of materials, such as gold/tin or tin/silver. The solder ball 60 encapsulates the top surface 53 of the conductive bump 50, the sidewall 55 of the cap 52, the space 56 and the sidewall 57 of the column 51. The solder ball 60 encapsulates the entirety of the conductive bump 50 and further encapsulates the sidewalls 41 of the UBM layer 40. Furthermore, in the operation of forming the space 56 of the conductive bump 50, the space 56 is filled by a part of the solder ball 60. After reflow and curing operations are performed on the solder ball 60, the solder ball 60 completely encapsulates the space 56 with solder filled within the space 56. The space 56 and the cap 52 form a structure in a shape similar to a clasp or reversed hook, where the principle of structural mechanics is leveraged to increase the adhesion between the solder ball 60 and the conductive bump 50, thereby preventing the solder ball 60 from dropping off the conductive bump 50. Also, the cap 52 protrudes laterally to encompass a larger contact area, as compared to conventional approaches which perform bonding on the UBM layer only. The contact area between the solder ball 60 and the conductive bump 50 is increased and the adhesion therebetween is thus improved effectively. The height of the space 56 (distance from the bottom 58 of the cap 52 to the upper surface of the passivation layer 30) is about 5-9 μm, which is about 60%-90% of the height H (distance from the top surface 53 of the cap 52 to the upper surface of the passivation layer 30). In one embodiment, the top surface 53 is a planar surface, thus the top surface 53 has a uniform height. In another embodiment, the top surface 53 has a curvature, such as a concave surface (the central part of the cap 52 is thinner than the periphery of the cap 52) or a convex surface (the central part of the cap 52 is thicker than the periphery of the cap 52). In another embodiment, the top surface 53 is a rough surface. A non-planar top surface 53 increases the contact area between the solder ball 60 and the conductive bump 50, and thus the adhesion between the solder ball 60 and the conductive bump 50 is increased further.

By way of the adjustment of the ratio between the column 51 and the cap 52 of the conductive bump 50, and the encapsulation over the solder ball 60 of the space 56, the sidewalls 41 of the UBM layer 40 and the conductive bump 50 by the solder ball 60, the contact area between the solder ball 60 and the conductive bump 50 is increased. The adhesion between the solder ball 60 and the conductive bump 50 is enhanced effectively, and bonding failure is thus alleviated.

It is shown in FIG. 1B that, after the UBM layer 40 is deposited, a patterned photoresist layer 62 is disposed to form the conductive bump 50. The patterned photoresist layer 62 has an opening 64 which is on the contact pad 20 and exposes part of the UBM layer 40. Specifically, the patterned photoresist layer 62 has a thickness of about 5-8 μm. After the patterned photoresist layer 62 is formed, an electroplating process is performed to form the conductive bump 50. Specifically, the electroplating metal is allowed to fill in and overflow outside the opening 64 so that the overflowed metal may form the cap 52. The methods for forming the conductive bump 50 comprise physical vapor deposition and chemical vapor deposition. The conductive bump 50 comprises gold, silver, copper, aluminum, tungsten, nickel, cobalt metal alloys, and/or the like. In an embodiment, the conductive bump 50 has a same metal with the uppermost layer of the UBM layer 40 (e.g., a seed layer). That means the conductive bump 50 is seen as an upward extension of the UBM layer 40, and thus regarded as part of the UBM layer 40. Subsequently, after the patterned photoresist layer 62 and a part of the UBM layer 40 are removed, the solder ball 60 is formed on the conductive bump 50. The methods for forming the solder ball 60 include electroplating, printing or ball bumping, and a subsequent reflow process. Therefore, the solder ball 60 can completely encapsulate the conductive bump 50 and be fixed on the conductive bump 50 (illustrated in FIG. 1A).

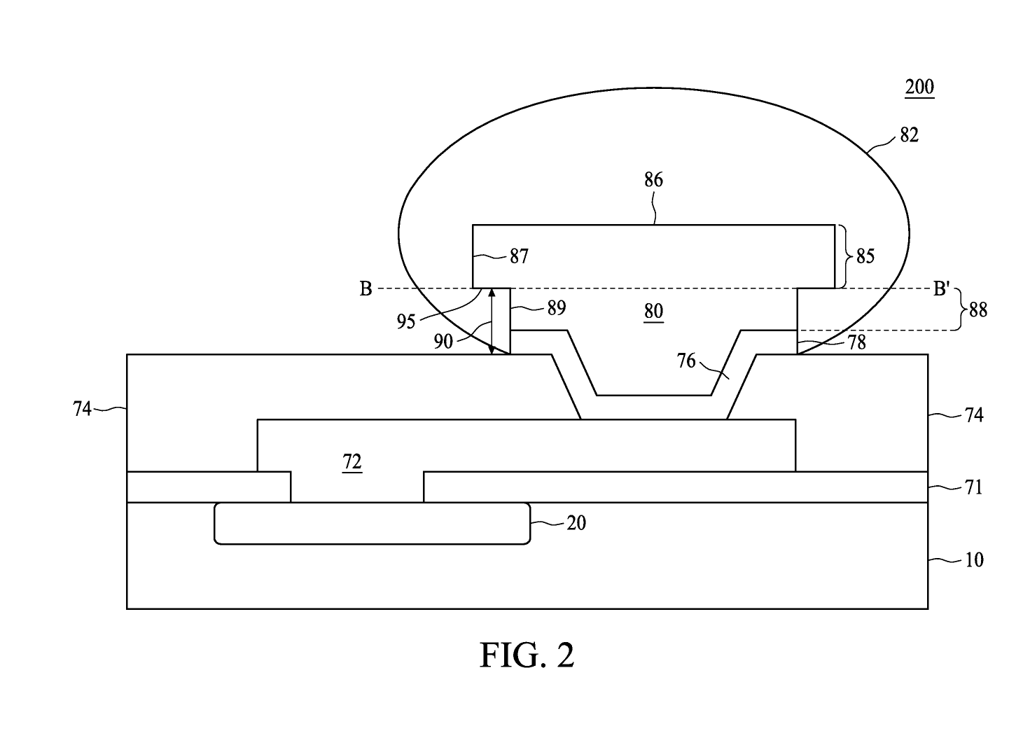

FIG. 2 is a cross-sectional view of a packaged semiconductor device 200 in accordance with some embodiments. The semiconductor structure 200 includes a substrate 10, a contact pad 20, a redistribution (RDL) layer 72, a protection layer 74 or a polymer layer, a UBM layer 76, a conductive bump 80 and a solder ball 82. The passivation layer 71 covers an active surface of the substrate 10 and has an opening which exposes part of the contact pad 20. The RDL layer 72 is a patterned metallization layer, which connects the contact pad 20 through the opening of the passivation layer 71 and allows the contact pad 20 to couple with the solder ball 82. The protection layer 74 covers the passivation layer 71 and part of the RDL layer 72, and the protection layer 74 has an opening which exposes part of the RDL layer 72. The UBM layer 76 is formed in the opening of the protection layer 74, and is connected with the RDL layer 72 through the opening of the protection layer 74. The conductive bump 80 is formed on the UBM layer 76, and includes a cap 85 and a column 88. The solder ball 82 encapsulates the entirety of the conductive bump 80 and sidewalls 78 of the UBM layer 76. More specifically, the solder ball 82 encapsulates a top face 86, sidewalls 87 of the cap 85 and sidewalls 89 of the column 88. The bottom area of the cap 85 (with reference to a section line BB′) is larger than the cross-sectional area of the column 88. In a lateral view, the width of a bottom 95 of the cap 85 (distance between the two sidewalls 87) is larger than the width of the bottom 85 of the UBM layer 76 (distance between two the sidewalls 78). The cap 85 protrudes laterally from the column 88 such that a space 90 is formed between the bottom 95 of the cap 85 and the upper surface of the protection layer 74, where the space 90 is filled with solder material. After reflow and curing processes are performed on the solder ball 82, the solder ball 82 encapsulates the space 90, the conductive bump 80 and the sidewalls 78 of the UBM layer 76. The space 90 and the cap 85 form a structure in a shape similar to a clasp or reversed hook, where the principle of structural mechanics is leveraged to increase the adhesion between the solder ball 82 and the conductive bump 80. Therefore, the solder ball 82 is kept from dropping off the conductive bump 80. In addition, the contact area between the solder ball 82 and the conductive bump 80 is increased, and the adhesion is thus improved effectively.

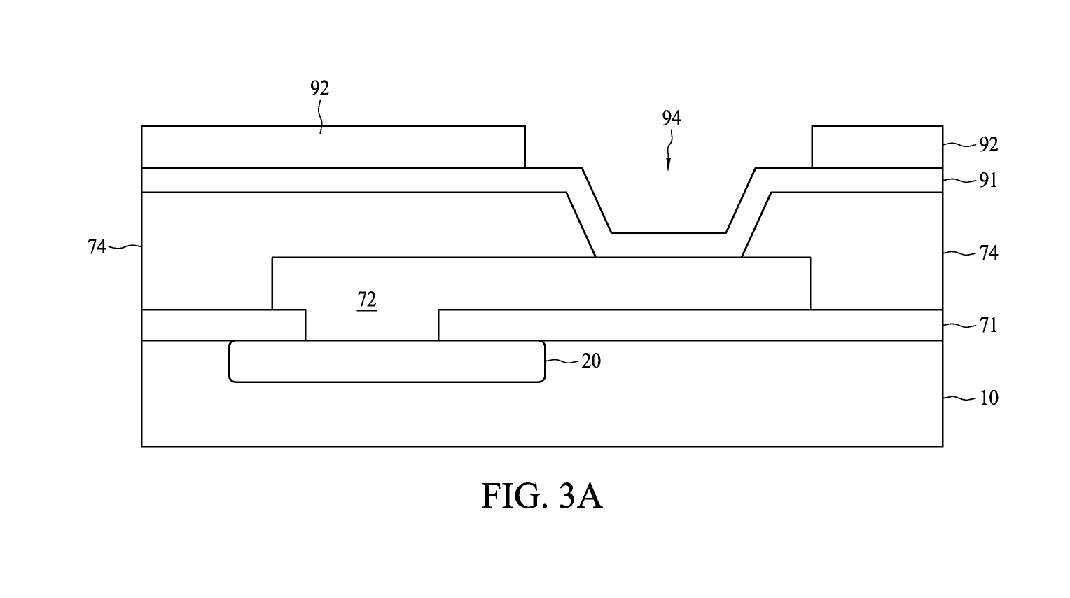

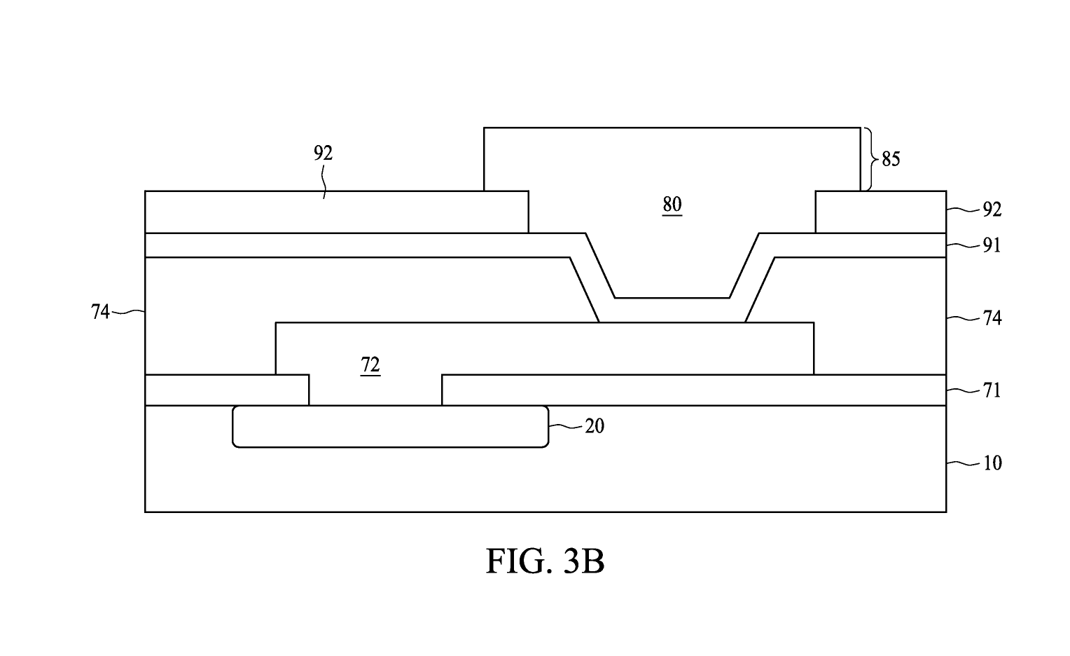

FIGS. 3A-3B are cross-sectional views of a method for manufacturing a packaged semiconductor device 200 in accordance with some embodiments. Referring to FIG. 3A, after a patterning process, the protection layer 74 has an RDL layer having an opening which exposes part of the RDL layer 72. A metallization layer 91 is deposited on the substrate 10 and covers the protection layer 74 and part of the RDL layer 72. The metallization layer 91 is connected with the RDL layer 72 through the opening of the protection layer 74. Subsequently, a patterned layer 92 is formed on the metallization layer 91 with an opening 94 exposing the metallization layer 91 thereunder. In another embodiment, the patterned layer 92 has a thickness of about 5-8

Referring to FIG. 3B, a metal material is deposited in the opening 94 using electroplating and, specifically, is allowed to fill in and overflow outside the opening 94. Consequently, part of the metal is disposed on the patterned layer 92, and thereby the cap 85 is formed. In an embodiment, the electroplating process is controlled to the extent that a planar top surface of the cap 85 is formed. In another embodiment, the electroplating process is controlled to the extent that the top surface of the cap 85 has a curvature, such as a concave or convex surface. In yet another embodiment, the conductive bump 80 can also be formed by a deposition process. Subsequently, the patterned layer 92 is removed and part of the metallization layer 91 is removed by etching so that the space 90 is formed at the removed parts from the patterned layer 92 and the metallization layer 91 below the cap 85. The height of the space 90 is equal to the combined thickness of the patterned layer 92 and the metallization layer 91. Afterward, an operation for forming solder balls is performed. The operation includes, but is not limited to, screen printing, vapor deposition, electroplating, ball dropping and ball spraying. In an embodiment, the solder ball 82 may be formed by an operation of ball dropping in cooperation with a stencil (not shown), where the solder ball 82 is disposed on the UBM layer 76 through the aid of the stencil. Furthermore, with a reflow operation on the solder ball 82, the entirety of the conductive bump 80, the sidewalls 78 of the UBM layer 76, and the space 90 between the conductive bump 80 and the protection layer 74 are encapsulated by the solder ball 82. Since the contact area between the solder ball 82 and the conductive bump 80 is increased due to the presence of the space 90, the adhesion is thus improved and the solder balls may be prevented from dropping.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A packaged semiconductor device, comprising:
a substrate comprising a contact pad;
a passivation layer disposed on the substrate, the passivation layer covering part of the contact pad;
an under bump metallization (UBM) layer disposed on the substrate, the UBM layer being coupled to the contact pad;
a conductive bump disposed on the UBM layer, the conductive bump comprising:
a column connecting the UBM layer; and
a cap disposed on top of the column, in which the cap includes a bottom area larger than a cross-sectional area of the column, and a bottom of the cap is distant from an upper surface of the passivation layer by a space; and
a solder ball encapsulating the conductive bump.

2. The packaged semiconductor device according to claim 1, wherein the bottom of the cap has a width larger than a width of the UBM layer.

3. The packaged semiconductor device according to claim 1, wherein the solder ball encapsulates a sidewall of the column and the space.

4. The packaged semiconductor device according to claim 1, wherein a top surface of the cap has a curvature with a central part of the cap that is thicker than a periphery of the cap.

5. The packaged semiconductor device according to claim 1, wherein a top surface of the cap has a curvature with a central part of the cap that is thinner than a periphery of the cap.

6. The packaged semiconductor device according to claim 1, wherein the conductive bump is made of gold, copper, nickel, silver or alloys thererof.

7. The packaged semiconductor device according to claim 1, wherein the UBM layer is made of titanium-copper, titanium-tungsten-gold, or silver-containing alloy.

8. A packaged semiconductor device, comprising:
a substrate comprising a contact pad;
a passivation layer disposed on the substrate with a first part of the contact pad exposed;
a redistribution layer disposed on the passivation layer and coupled with the first part of the contact pad;
a protection layer disposed on the redistribution layer with a second part of the passivation layer exposed;
an under bump metallization (UBM) layer disposed on the protection layer, the UBM layer being coupled to the second part of the passivation layer;
a conductive bump disposed on the UBM layer, the conductive bump comprising:
a column connecting the UBM layer; and
a cap disposed on top of the column, in which the cap includes a bottom area larger than a cross-sectional area of the column, and a bottom of the cap is distant from an upper surface of the passivation layer by a space; and
a solder ball encapsulating the conductive bump.

9. The packaged semiconductor device according to claim 8, wherein the bottom of the cap includes a width larger than a width of the UBM layer.

10. The packaged semiconductor device according to claim 8, wherein the solder ball encapsulates a sidewall of the column and the space.

11. The packaged semiconductor device according to claim 8, wherein a top surface of the cap has a curvature with a central part of the cap that is thicker than a periphery of the cap.

12. The packaged semiconductor device according to claim 8, wherein a top surface of the cap has a curvature with a central part of the cap that is thinner than a periphery of the cap.

13. The packaged semiconductor device according to claim 8, wherein the space has a height of 5 μm to 9 μm.

14. The packaged semiconductor device according to claim 8, wherein the space has a height of 60%-90% of the distance from the upper surface of the passivation layer to a top surface of the cap.

15. The packaged semiconductor device according to claim 8, wherein the conductive bump is made of gold, copper, nickel, silver or alloys thererof.

16. The packaged semiconductor device according to claim 8, wherein the UBM layer is made of titanium-copper, titanium-tungsten-gold, or silver-containing alloy.

17. A method for manufacturing a packaged semiconductor device, the method comprising:
forming a substrate comprising a contact pad;
forming a passivation layer on the substrate while exposing a first part of the contact pad;
forming an under bump metallization (UBM) layer on the substrate in order to couple the UBM layer with the contact pad;
forming a conductive bump on the UBM layer; and
forming a solder ball encapsulating the conductive bump;
wherein forming the conductive bump further comprises:
forming a column connecting the UBM layer; and
forming a cap on top of the column, in which the cap includes a bottom area larger than a cross-sectional area of the column, and a bottom of the cap is distant from an upper surface of the passivation layer by a space.

18. The method according to claim 17, wherein forming a UBM layer further comprises forming the UBM layer by titanium-copper, titanium-tungsten-gold, or silver-containing alloy.

19. The method according to claim 17 further comprising forming a patterned photoresist layer on the UBM layer while exposing a second part of the UBM layer.

20. The method according to claim 19, wherein the patterned photoresist layer has a thickness of from 5 μm to 8 μm.
